(19) United States
(12) Patent Application Publication
(10) Pub. No.: US 2026/0096475 A1
(43) Pub. Date: Apr. 2, 2026

(54) CHIP PACKAGE WITH MULTI-TIER STACKS

(71) Applicant: Advanced Micro Devices, Inc., Santa Clara, CA (US)

(72) Inventors: Deepak Vasant KULKARNI, Austin, TX (US); Samuel NAFFZIGER, Fort Collins, CO (US)

(21) Appl. No.: 18/902,608

(22) Filed: Sep. 30, 2024

(51) Int. Cl. H01L 25/16; H01L 23/14; H01L 23/48; H01L 23/538; H01L 25/18; H10B 80/00

(52) U.S. Cl. CPC H10W 90/00; H10W 20/20; H10W 70/611; H10W 90/401; H10B 80/00; H10W 70/695

(57) ABSTRACT

Disclosed herein are chip packages and methods for fabricating and operating the same. In one example, a chip package is provided that includes a first die stack having a first side mounted to a first interposer, a first I/O die having a first side mounted to the first interposer, and a first compute die complex mounted on a second side of the first die stack. The first compute die complex including at least a first compute die having functional circuitry coupled to circuitry of the first I/O die through vias extending through the first die stack.

### TECHNICAL FIELD

Embodiments of the present invention generally relate to chip packages having memory die stacks, and in particular, chip packages that interface one or more compute die complexes with one or more die stacks within a singular chip package.

### BACKGROUND

Electronic devices, such as tablets, computers, copiers, digital cameras, smart phones, control systems, automated teller machines, data centers, artificial intelligence system, and machine learning systems among others, often employ electronic and/or photonics components which leverage chip packages for increased functionality and higher component density. Conventional chip packaging schemes often utilize a package substrate, often in conjunction with a through-silicon-via (TSV) interposer substrate and/or other such as fanout and/or silicon bridging and/or substrate with glass and/or Si and/or organic core, to enable a plurality of integrated circuit (IC) dies to be mounted to a single package substrate. The IC dies are mounted to a top side of the package substrate while a bottom side of the package substrate is mounted to a printed circuit board (PCB).

In many applications, memory dies are integrated into the chip package to reduce the distance between the memory dies and compute dies of the chip package. The shortened distance reduces power consumption and increases device performance. One type of chip package having both a stack of memory dies and at least one connected compute die is known as a high bandwidth memory (HBM). The HBM stack conventionally includes an I/O buffer die upon which the memory dies are stacked. The I/O buffer die also includes the memory controller. However, in most conventional chip packages having a HBM die stack generally have compute dies that have complex route between each compute die and the I/O buffer and memory dies of with a particular HBM die stack, often requiring routing through the package substrate. The complex routing creates scheduling complexity that slows device performance. The long routing lengths present in conventional chip packages also results in slower transmission times and high die-to-die interconnect power consumption.

Additionally, the complex routing often requires a larger, more expensive interposer and package substrate to accommodate the increased number of routing traces without generating excessive unwanted noise. The larger interposers and package substrates increase the manufacturing complexity, lead times, and cost, and contribute to slower performance, all of which are undesirable.

Therefore, a need exists for improved chip packages that efficiently interface one or more compute dies with die stacks, such as memory, ASIC, or other type of die stack) within a singular chip package.

### SUMMARY

Disclosed herein are chip packages and methods for fabricating and operating the same. In one example, a chip package is provided that includes a first die stack having a first side mounted to a first interposer, a first I/O die having a first side mounted to the first interposer, and a first compute die complex mounted on a second side of the first die stack. The first compute die complex includes at least a first compute die having functional circuitry coupled to circuitry of the first I/O die through vias extending through the first die stack. The first die stack may be a memory die stack, an ASIC die stack, a compute die stack or other type of heterogeneous or homogeneous stack of dies.

In another example, a chip package is provided that includes a first interposer, a first memory die stack mounted to the first interposer, a second memory die stack mounted to the first interposer laterally adjacent the first memory die stack, a first I/O die mounted to the first interposer, a second I/O die mounted to the first interposer, a second interposer disposed on the first and second die stacks and the first and second I/O dies, and a first compute die complex mounted on the second interposer above the first and second memory die stacks. The first and second die stacks are disposed between the first and second I/O dies. The first compute die complex includes at least a first compute die having functional circuitry coupled to circuitry of the first I/O die through vias extending through the first memory die stack.

In yet another example, a method for operating a chip package is provided. The method includes transmitting data signals from a package substrate to a first interposer mounted on the package substrate, transmitting the data signals through the first interposer into an I/O die mounted on the first interposer, transmitting the data signals from I/O die mounted through the first interposer to vias formed through a memory die stack, and transmitting the data signals from the vias formed through the memory die stack to an IC compute die disposed above the memory die stack.

In still yet another example, a method for fabricating a chip package is provided. The method includes the operations of affixing top sides of a plurality of memory die stacks and a plurality of I/O dies on a carrier; mounting bottom sides of a plurality of memory die stacks and a plurality of I/O dies on a first interposer; forming a redistribution layer (RDL) layer on the top sides of the plurality of memory die stacks and the plurality of I/O dies; and mounting a first compute die complex on the RDL layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A and 1B are schematic sectional views of two examples of a chip package having a die stack, an I/O die, a compute die complex and two interposers. The die stack and the I/O die are mounted between the two interposers, while the compute die complex is mounted on the one of the two interposers via solder interconnects.

FIGS. 2A and 2B are schematic signal routing diagrams for the chip packages illustrated in FIGS. 1A and 1B.

FIG. 3 is flow diagram of one example of a method for operating an electronic device, such as the chip package described in FIG. 1A.

FIG. 4A through FIG. 4G depict a chip package, such as the chip package illustrated in FIG. 1A among others, in various stages of assembly.

FIG. 5 is a flow diagram of a method for fabricating one example of a chip package, the stages of which are illustrated by FIGS. 4A-4G.

To facilitate understanding, identical reference numerals have been used, where possible, to designate identical elements that are common to the figures. It is contemplated that elements of one embodiment may be beneficially incorporated in other embodiments.

### DETAILED DESCRIPTION

Disclosed herein are chip packages that integrate compute and memory dies in a multi-tier stack. Generally, one or more compute dies are stacked on top of a memory die stack in a manner that leverages an embedded fanout bridge (EFB), chip on wafer on substrate (CoWoS), and redistribution layer (RDL) fabrication techniques to yield chip packages having shorter routings, better performance and greater fabrication yields as compared to conventional arrangements that utilize conventional fabrication processes. The use of an RDL layer to connect compute dies and the memory die stack beneficially enables the use of ultra-fine pitch solder interconnects (˜25 μm or lower). The short routing lengths beneficially results in less energy consumed while transferring data between logic and memory dies. Moreover, the use of solder based interconnects between the compute die and the memory die stack improves fabrication yield since the memory die stacks can be built and tested prior to combining with the compute dies. Furthermore, through-silicon-vias in the memory die stacks provides more efficient power delivery. Additionally, stacking the compute and memory dies improves wafer utilization, while also improving thermal management within the chip package. The stacking the compute and memory dies also allows I/O to be concentrated at the edges of the chip package, freeing space at the center of the chip package for power delivery.

Stacking of memory and compute dies also improves wafer utilization by building memory die stacks and compute stacks separately, unlike wafer on wafer processes that impose the same wafer level reticle pattern for both logic and memory dies, which can result in up to 30 percent wasted space on memory die wafer.

Furthermore, cycle time is improved by enabling memory die stacks and compute die complexes to be fabricated in parallel, rather than serially as done in conventional manufacturing processes. The separate process flows allows more efficient scaling while using less reticles as compared to traditional assembly processes. The separate process flows and modular arrangement of the chip package components also enables increased manufacturing flexibility at reduced costs. The number and position of the modular arrangement components of the chip package may be selected and arranged for various compute applications without the need for new die or interposer designs. As a result, the chip package described herein provides increased application flexibility at reduced manufacturing costs.

In one example, a chip package is provided that includes a first die stack having a first side mounted to a first interposer, a first I/O die having a first side mounted to the first interposer, and a first compute die complex mounted on a second (i.e., top) side of the first memory die stack. The first compute die complex includes at least a first compute die having functional circuitry coupled to circuitry of the first I/O die through vias extending through the first die stack. The first die stack may be a memory die stack, an ASIC die stack, a compute die stack or other type of heterogeneous or homogeneous stack of dies.

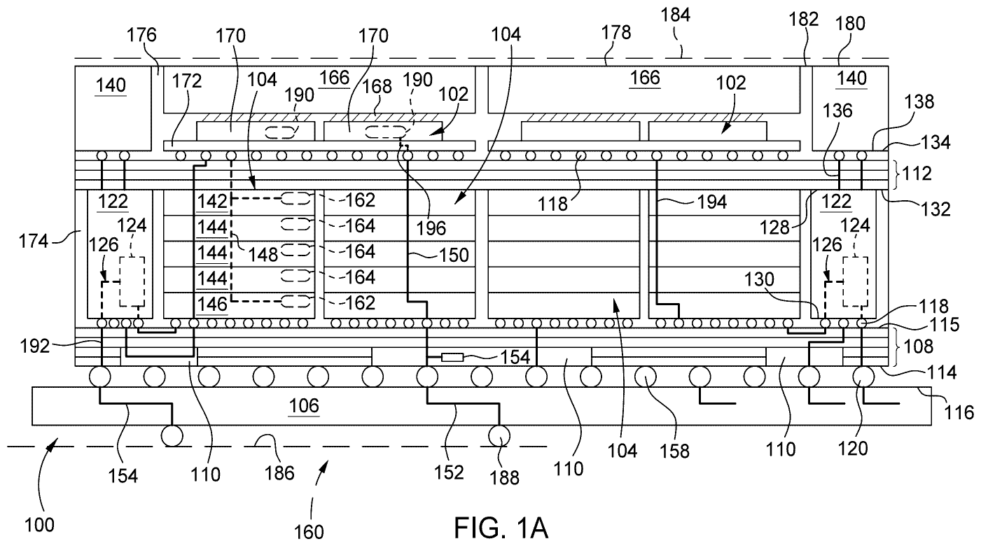

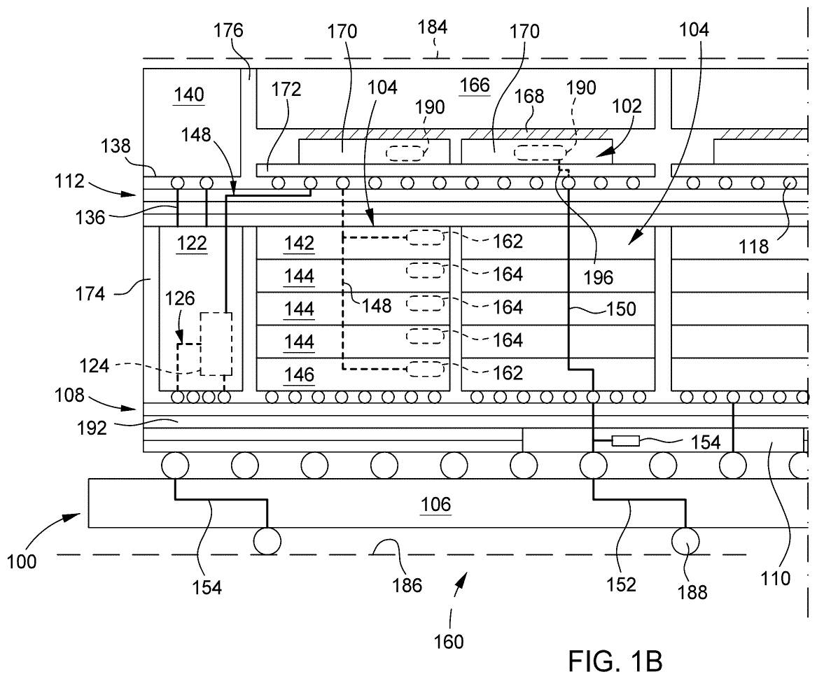

Turning now to FIG. 1A, a schematic sectional view of one example of a chip package 100 is provided. The chip package 100 includes at least one memory die stack 104, at least one I/O die 122, at least one compute die complex 102 and two interposers 108, 112. The memory die stack 104 and the I/O die 122 are mounted between the two interposers 108, 112, while the compute die complex 102 is mounted on the one of the two interposers (i.e., the second interposer 112) via solder interconnects 118. The compute die complex 102 includes at least one or more compute dies 170. Although in the exemplary the chip package 100 includes two compute die complex 102 shown in FIG. 1A, the chip package 100 may include one to as many compute die complex 102 as space permits to achieve desired functionality. Similarly, the chip package 100 illustrated in FIG. 1A may include one to as many memory die stacks 104 as space permits to achieve desired functionality.

As briefly discussed above, the memory die stack 104 may alternatively be a stack of another type or types of IC dies, such as a homogeneous stack of ASIC dies, a homogeneous stack of compute dies, a homogeneous stack of other types of IC dies, or a heterogeneous stack of ASIC dies, a heterogeneous stack of compute dies, or a heterogeneous stack of other types of IC dies, among others. In the example depicted in FIG. 1A, the dies stack is a stack of memory dies. The memory die stack 104 includes a top memory die 142, one or more intervening memory dies 144, and a bottom memory die 146. Each of memory dies 142, 144, 146 within each memory die stack 104 can be interconnected via solder interconnect, via hybrid bonding, or other suitable technique. The memory dies 142, 144, 146 within a common memory die stack 104 include memory circuitry 162, 164 that may be volatile memory, such as static random-access memory (SRAM), dynamic random-access memory (DRAM) or other suitable volatile memory type. Optionally, one or more of the memory dies 142, 144, 146 within a common memory die stack 104 include memory circuitry 162, 164 that may be non-volatile memory, such as ferroelectric random-access memory (FeRAM) and magnetoresistive random-access memory (MRAM) or other suitable non-volatile memory type. The memory circuitry 162, 164 of the memory dies 142, 144, 146 of one memory die stack 104 may be the same or different than the memory circuitry 162, 164 of the memory dies 142, 144, 146 of another memory die stack 104 disposed in another region of the chip package 100. In one example, one or both of the top memory die 142 and the bottom memory die 146 of the memory die stack 106 has memory circuitry 164 that include memory controller circuitry. The number of intervening memory dies 144 within common memory die stack 104 may range from 2 to as many as desired. In one example, the number of intervening memory dies 144 within common memory die stack 104 is 4 to about 14 or more. The number of memory dies 142, 144, 146 within different memory die stacks 104 of the chip package 100 typically are the same. However, memory die stacks 104 having different numbers of memory dies 142, 144, 146 may be utilized. When memory die stacks 104 having different numbers of memory dies 142, 144, 146 are utilized, the memory die stacks 104 may be configured to have the same height. For example, the height difference between stacks 106 may be compensated for by using memory dies 142, 144, 146 having different thicknesses and/or the use of one or more dummy dies on top of the memory die stack 104.

The memory die stacks 104 are mounted on a top side 115 of the first interposer 108 via solder interconnects 118. The solder interconnects 118 may be microbumps or other suitable connection that mechanically and electrically connects the routing of the first interposer 108 to the circuitries of the memory die stacks 104.

One or more I/O dies 122 are also mounted on the top side 115 of the first interposer 108 via solder interconnects 118. Although in the exemplary the chip package 100 shown in FIG. 1A includes two I/O dies 122, the chip package 100 may include one to as many I/O dies 122 as space permits to achieve desired functionality. The solder interconnects 118 mechanically and electrically connects the routing of the first interposer 108 to the circuitries of the I/O dies 122.

The I/O die 122 generally includes I/O routing circuitry 126 that enables communication between the inputs and outputs of the chip package 100 with the compute dies 170 disposed within the chip package 100. The I/O routing circuitry 126 of each I/O die 122 includes serializer deserializer (SERDES) circuitry 124 and the like to facilitate high-speed communication with the chip package 100.

The first interposer 108 also includes a bottom side 114 that is coupled to a substrate. The substrate shown in FIG. 1A is a package substrate 106. Alternatively, the substrate may include both a silicon (or glass, ceramic, etc.) interposer and a package substrate 106, wherein the silicon interposer is mounted between the package substrate 106 and the first interposer 108. The package substrate 106 is electrically and mechanically coupled to the first interposer 108 by solder interconnects 120. The solder interconnects 120 may be solder bumps or other suitable electro mechanical connection.

The side of the package substrate 106 facing away from the first interposer 108 includes a plurality of exposed bond pads. The exposed bond pads may be configured to mate with a complimentary receiving structure formed on a top side of a printed circuit board (PCB) 186 to form an electronic device 150. The corresponding receiving structure formed on the top side of the PCB 186 may be a socket, or alternatively as illustrated in FIG. 1A, be in the form of a bond pad exposed on the top side of the printed circuit board 186 to form the electronic device 150. In one the example depicted in FIG. 1A, solder balls 188 connect the bond pads exposed on the bottom side 114 of the package substrate 106 to the bond pad exposed on the top side of the printed circuit board 186.

Returning back to the description of the first interposer 108, the first interposer 108 is electrically and mechanically coupled to the memory die stack 104 and the active interposer 172 by solder interconnects 118. The interconnects 118 may be solder bumps or other suitable electro mechanical connection. Alternatively, the first interposer 108 is electrically and mechanically coupled to the memory die stack 104 and the active interposer 172 via hybrid bonding or other suitable technique. The first interposer 108 includes first interposer routing 192 that connects the circuitry (shown in FIG. 1A as power routing circuitry 152 and data routing circuitry 154) of the package substrate 106 to the functional circuitry of the memory die stacks 104, circuitry 126 of the I/O dies 122, and the functional circuitry of the IC compute dies 170.

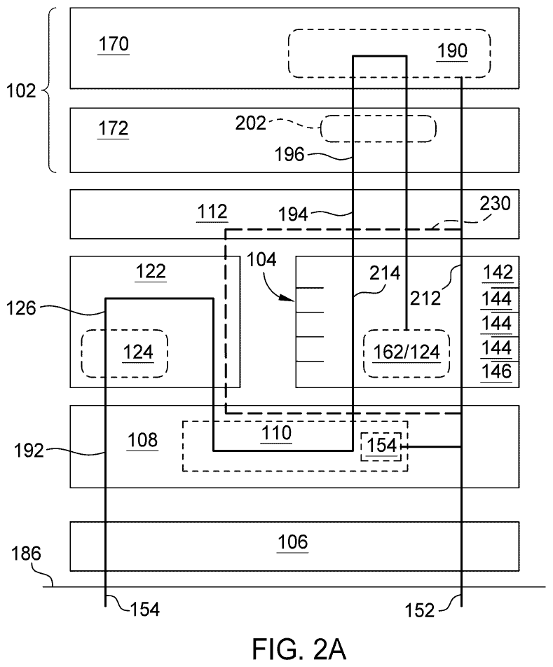

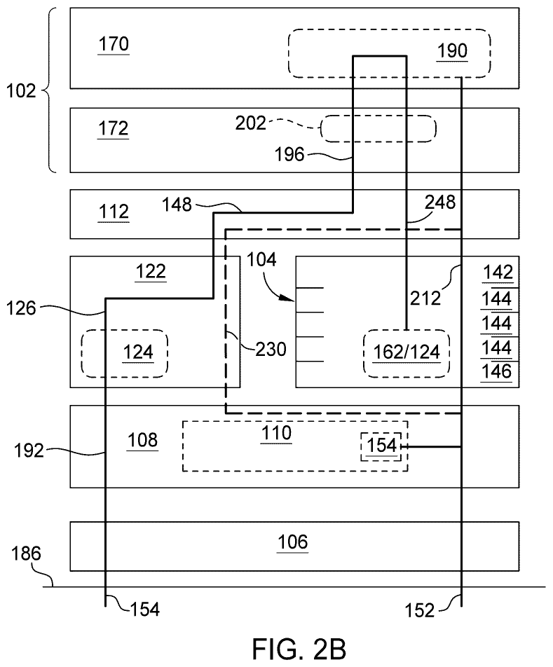

In one example, the first interposer 108 is an organic interposer formed from patterned metal layers separated by dielectric layers. The patterned metal layers form the first interposer routing 192. The first interposer 108 may also include an optional bridge die 110. The bridge die 110 includes passive high-density routings formed by back end of the line (BEOL) fabrication techniques. The bridge die 110 may also include passive devices formed therein, such as capacitors, resistors, inductors and the lie. In the example depicted in FIG. 1A, the bridge die 110 includes one or more decoupling capacitors 154. The decoupling capacitors 154 formed in the bridge die 110 may be coupled to the power routing circuitry 152 passing through the first interposer 108 as later detailed below with reference to FIG. 2.

Continuing to refer to FIG. 1A, the memory die stacks 104 and the I/O dies 122 are generally encapsulated by a first mold compound 174. The first mold compound 174 generally provides structural rigidity to the assembly of memory die stacks 104 and the I/O dies 122, while protecting the solder interconnects 118 disposed between the top side 115 of the first interposer 108 and the facing surfaces of the memory die stacks 104 and the I/O dies 122. The top sides of the first mold compound 174, the memory die stacks 104, and the I/O dies 122 (i.e., the sides facing away from the first interposer 108 and the package substrate 106) are generally made substantially coplanar to allow formation of the second interposer 112 thereon.

The second interposer 112 is formed from patterned metal layers separated by dielectric layers. The patterned metal layers form routing (e.g., second interposer routing 194) through the second interposer 112. The second interposer routing 194 is exposed on a bottom side 132 of the second interposer 112 where the exposed second interposer routing 194 is electrically connected to the circuitry extending through the memory die stack 104, as further described below with reference to FIG. 2. The exposed second interposer routing 194 may be electrically connected to the circuitry extending through the memory die stack 104, for example by plating the first patterned metal layer during the formation of the second interposer 112 on the terminations of the circuitry exposed on the surface of the memory die stack 104.

Continuing to refer to FIG. 1A, the second interposer 112 may also include electrically floating thermal vias 136. The thermal vias 136 may optionally be grounded. The thermal vias 136 are generally formed in contact with at least a top side 128 of the I/O die 122. The thermal vias 136 may be copper, aluminum or other good thermally conductive material. The thermal vias 136 direct heat upwards from the top side 128 of the I/O die 122 to a top side 134 of the second interposer 112. In this manner, heat is efficiently removed from interior portions of the chip package 100.

A dummy die 140 may be mounted to the top side 134 of the second interposer 112 over the thermal vias 136, and as such, over the top side 128 of the I/O die 122. Solder interconnects 118 may connect the thermal vias 136 to a bottom side 138 of the dummy die 140 to more efficiently transfer heat from the I/O die 122 to the dummy die 140. The dummy die 140 is fabricated from a good heat conductor, such as silicon, but may alternatively be fabricated from metal or be part of a heat sink or active heat transfer device mounted to the chip package 100. In the example depicted in FIG. 1A, the dummy die 140 is a silicon block having no active circuitry. The dummy die 140 may optionally include thermal vias (not shown) for further promoting heat transfer from the bottom side 138 to a top side 180 of the dummy die 140.

The top side 134 of the second interposer 112 is electrically and mechanically coupled to the circuitry of the compute die complex 102 by the solder interconnects 118. As discussed below, the solder interconnects 118 may be microbumps or other suitable connection that mechanically and electrically connects the routing 136 of the second interposer 112 to the circuitries of the compute die complex 102. Advantageously, the use of the solder interconnects 118 to connect the compute die complex 102 and dummy dies 140 to the second interposer 112 allows the assembly of the memory die stacks 104 and the compute die complex 102 to occur separately prior to connecting the assemblies via the solder interconnects 118. In this manner, wafer utilization and design cycle time are improved, while costs are decreased. Also, as the memory die stacks and compute die complexes are fabricated and tested separately, rather than serially as done in conventional manufacturing processes, more efficient scaling is enabled as compared to traditional assembly processes, while also increasing manufacturing flexibility at reduced costs. Moreover, the use of separately built memory die stacks and compute die complexes increases design flexibility, while advantageously reducing the time to market.

As discuss above, the compute die complex 102 generally includes at least one compute die 170. The compute die complex 102 may also include an active interposer 172 on which the one or more compute dies 170 are mounted. In the example depicted in FIG. 1A, two compute dies 170 are shown mounted on the active interposer 172. However, the number of compute dies 170 mounted on a single active interposer 172 may range from one to as many as desired (and as space enables).

Each compute die 170 includes functional circuitry 190. The functional circuitry 190 for each compute die 170 in a common compute die complex 102 may be the same or different. In one example, at least one or both of the first compute die 170 and the second compute die 170 include central processing unit (CPU) cores. As such, the first and second compute dies 170 containing CPU cores may be referred to as a CPU die or CPU chiplet. The functional circuitry 190 of the first and second compute dies 170 may also include System Management Unit (SMU). The SMU is circuitry configured to monitor thermal and power conditions and adjust power and cooling to keep the dies 170 functioning as within specifications. The functional circuitry 190 of the first and second compute dies 170 may also include Dynamic Function eXchange (DFX) Controller IP circuitry. The DFX circuitry provides management of hardware or software trigger events. For example, the DFX circuitry may pull partial bitstreams from memory and delivers them to an internal configuration access port (ICAP). The DFX circuitry also assists with logical decoupling and startup events, customizable per Reconfigurable Partition.

In another example, the functional circuitry 190 of at least one or both of both the first compute die 170 and the second compute die 170 include accelerated compute cores. As such, each of the first and second compute dies 170 containing accelerated compute cores may be referred to as an accelerator die or accelerator chiplet. The first and second compute dies 170 containing accelerated compute cores may also be referred to as a graphic processing unit (GPU) die or GPU chiplet. The accelerated compute cores contained in the functional circuitry 190 of the first and second compute dies 170 generally includes math engine circuitry. The math engine circuitry is generally designed for task specific computing, such as used data center computing, high performance computing and AI/ML computing. Along with the accelerated compute cores, functional circuitry 190 of the first compute die 170 and the second compute die 170 may also include SMU circuitry and DFX circuitry.

In other examples, the functional circuitry 190 the first compute die 170 and the second compute die 170 are different. For example, the first compute die 170 may include accelerated compute cores, while the second compute die 170 includes CPU cores. One or more compute dies, when present in the compute stack 104, may include CPU cores and/or an accelerated compute cores.

As briefly discussed above, the one or more compute dies 170 may be mounted on a common active interposer 172. The active interposer 172 has interposer routing 196 that connects the functional circuitry 190 of the compute dies 170 to the routing circuitry 194 of the second interposer 112 via the solder interconnects 118. The interposer routing 196 of the active interposer 172 may be connect functional circuitry 190 of the compute dies 170 via interconnects, such as solder bumps, hybrid bonding, or other suitable technique. In the example depicted in FIG. 1A, the functional circuitry 190 of the compute dies 170 is hybrid bonded to the interposer routing 196 of the active interposer 172.

The compute die complex 104 may additionally include one or more carrier dies 166 disposed over the compute dies 170. The carrier die 166 generally is the top die in the compute die complex 104, located farthest from the active interposer 172. The carrier die 166 is generally a block of silicon material that provides good heat transfer out of the compute die complex 104. The carrier die 166 may be thicker than one or both of the compute dies 170, thus providing increased structural rigidity and increase resistance to warpage within the compute die complex 104, which makes connections between compute dies 170 more reliable and robust. The carrier die 166 may be circuit free, i.e., free from routing, passive and active circuit devices. The carrier die 166 is adhered to one or both of the compute dies 170 within the compute die complex 104. In other examples, a carrier die 166 may be adhered to compute dies 170 in adjacent compute die complexes 104 of the chip package 100. The carrier die 166 may be adhered to the compute die(s) using any suitable adhesive or technique. In one example, the carrier die 166 is fusion bonded to the compute die(s) 170. In such an example, an oxide layer is disposed between the carrier die 166 and the compute die(s) to enhance the fusion bonding process. Fusion bonding increases the structural rigidity of the compute die complex 104, and makes connections between compute dies 170 more reliable and robust. In other examples, an adhesive thermal interface material (TIM) 168 may be used to secure the carrier die 166 to the compute die(s) 170 of the compute die complex 104.

The compute die complexes 104 and the dummy dies 140 are generally encapsulated by a second mold compound 176. The second mold compound 176 may be of the same or different type of material as the first mold compound 174 described above. The second mold compound 176 generally provides structural rigidity to the assembly of compute die complexes 104 and the dummy dies 140, while protecting the solder interconnects 118 disposed between the top side 134 of the second interposer 112 and the facing surfaces of the compute die complexes 104 and the dummy dies 140.

The top sides 178, 180, 182 of the second mold compound 176, compute die complexes 104 and the dummy dies 140 (i.e., the sides facing away from the second interposer 108 and the memory die stacks 104) are generally made substantially coplanar to allow the chip package 100 to interface with a heat sink or active thermal management device (such as a forces fluid heat exchanger). In the example depicted in FIG. 1A, the top sides 178, 180, 182 of the second mold compound 176, compute die complexes 104 and the dummy dies 140 are optionally covered by a thin metal layer 184 to promote heat transfer to the heat sink or active thermal management device. The metal layer 184 may be copper, aluminum, nickel, other suitable material.

Continuing to refer to FIG. 1A, the package substrate 106 may also include surface mounted components (not shown) that are coupled to functional circuitry within the chip package 100. The surface mounted components may be integrated passive devices (IPDs), such as capacitors, inductors, and resistors, among others. In one example, the surface mounted components are capacitors. In addition or alternatively, some or all of the surface mounted components may be located as IPDs in other locations of the chip package 100. For example, IPDs may be located within or attached to one or more of the interposers 108, 112, 172, within the package substrate 106, or other suitable location within the chip package 100.

FIG. 1B is a schematic sectional view of another example of a chip package 100 which depicts alternative routing of data signals between the package substrate 106 and the compute die complex 102. In the example depicted in FIG. 1B, the routing circuitry 126 of the I/O die 122 is connected to data routing 148 formed in the second interposer 112. The data routing 148 is connected via the solder interconnects 118 to the active interposer 172 of the compute die complex 102.

FIG. 2A is a schematic signal routing diagram for one example of a chip package, such as the chip package 100 described above with reference to FIG. 1A, among others. In the diagram depicted in FIG. 2A, the power routing 152 and data signal routing 154 though the chip package 100 is illustrated. Although only one exemplary power routing 152 and one exemplary data signal routing 154 are shown in FIG. 2A, it is understood that the chip package 100 has many additional routings 152, 154 that are omitted for the sake of clarity.

A data signal is transmitted along the data signal routing 154 between the package substrate 106 to the compute die 170, among other components of the chip package 100. The data signal enters the package substrate 106 of chip package 100 from the PCB 186. The data signal is transmitted from the circuitry of the package substrate 106 to the circuitry 192 to the circuitry 126 of the first interposer 108. The data signal may optionally be routed through the bridge die 110 prior to being transmitted from the circuitry 192 of the first interposer 108 to the circuitry 126 of the I/O die 122. In the I/O die 122, the data signal is routed through the SERDES circuitry 124 prior to returning to the circuitry 192 of the first interposer 108.

The data signal is then routed optionally through the bridge die 110 prior to being transmitted from the circuitry 192 of the first interposer 108 to a data via 214 formed through the memory dies 142, 144, 146 of the memory die stack 104 directly to the compute die complex 102. The data via 214 allows the compute die complex 102 to be mounted closer to the top surface of the chip package 100, this allowing heat to be more readily removed, advantageously without excessive heat transfer to the memory dies 142, 144, 146 of the memory die stack 104.

The data signal is then routed within the compute die complex 102 through functional circuitry 202 of the active interposer die 172 to the functional circuitry 190 of the compute die 170. The functional circuitry 202 of the active interposer 172 illustrated in FIG. 2A may optionally include memory controller circuity coupled to one or both of the first and second compute dies 170 without having to be routed through a package substrate as found in conventional designs. The functional circuitry 202 of the active interposer 172 may also include cache memory circuity. The cache memory circuity is coupled to both the first and second compute dies 170 without routing signals through a package substrate as found in conventional designs. The cache memory circuity provides a large common cache for the compute dies 170 of the compute stack 104 that are mounted to the active interposer 172.

The functional circuitry 202 of the active interposer 172 may also include peripheral component interconnect express (PCIe) circuity, memory physical layer (PHY) circuitry configured to communicate with the memory die stack 104, die to die PHY configured to communicate with at least one or more compute die complex 102, and I/O PHY configured to communicate with an integrated circuit device remote from the chip package 100, or a printed circuit board 186 via the package substrate 106. The I/O PHY may also be configured to communicate with other compute die complexes 102 that are remove from the interposer die 172 in which the I/O PHY resides but within the same chip package 100. The I/O PHY may also be configured to communicate with other memory die stacks 104 residing in the chip package 100. The functional circuitry 202 of the active interposer 172 may also one or more other functional blocks for performing other functions of a network on a chip (NOC).

From the functional circuitry 190 of the compute die 170, the data signal is then routed back through the functional circuitry 202 of the active interposer 172 to the memory controller circuitry 162 residing in one or both of the top memory die 142 and/or the bottom memory die 144. From the memory controller circuitry 162, the data signal is then routed to an appropriate one of the memory circuitries 164 of the memory dies 142, 144, 146.

Data signals read from memory circuitries 164 of the memory dies 142, 144, 146 and/or product by the functional circuitries 190 of the compute dies 170 is routed out of the chip package in the reverse manner.

FIG. 2A also depicts routing of a power signal is transmitted along the power signal routing 152 defined between the package substrate 106 to the compute die 170, among other components of the chip package 100. The power signal enters the package substrate 106 of chip package 100 from the PCB 186. The power signal is transmitted from the circuitry of the package substrate 106 to the circuitry 192 to the circuitry 126 of the first interposer 108. The power signal may optionally be routed through the bridge die 110 prior to being transmitted from the circuitry 192 of the first interposer 108 to the circuitry 126 of the I/O die 122. In the bridge die 110 (or other location within the chip package 100), the power signal connected to the decoupling capacitor 154 prior to being transmitted to a power via 212 formed through the memory dies 142, 144, 146 of the memory die stack 104. The power via 212 couples the power signal leaving the first interposer 108 directly to the compute die complex 102. This short and direct routing of power from the package substrate 106 to the compute die complex 102 advantageously reduces power consumption compared to conventional designs. Alternatively, the power signal may be transmitted on a by-pass routing 230 that is routed from the first interposer 108, through the I/O die 122, and through the second interposer 112 to the compute die complex 102, while by-passing (i.e., not being routed through) the memory die stack 104.

Although not shown, ground is provided in an identical manner as described with reference to the power routing 152, using dedicated ground vias formed through the memory dies 142, 144, 146 as shown with respect to the power vias 212, or alternatively by using the by-pass routing 230 to couple ground from the first interposer 108, through the I/O die 122, and through the second interposer 112 to the compute die complex 102, while by-passing (i.e., not being routed through) the memory die stack 104.

FIG. 2B is a schematic signal routing diagram for another example of a chip package, such as the chip package 100 described with reference FIG. 1B, among others. In the diagram depicted in FIG. 2B, the power routing 152 (and ground routing) is the same as described with reference to the routing diagram of FIG. 2A, either using vias formed through the memory stack 104 or utilizing by-pass routing 230 that directs connecting through the I/O die 122 instead of the memory die stack 104. In FIG. 2B, the data signal routing 154 is not routed through the memory die stack 104, but rather routed directly from the I/O die 122 through the data routing 148 formed in the second interposer 112 to the compute die complex 102.

As shown in FIG. 2B, a data signal is transmitted along the data signal routing 154 between the package substrate 106 to the compute die 170, among other components of the chip package 100. The data signal enters the package substrate 106 of chip package 100 from the PCB 186. The data signal is transmitted from the circuitry of the package substrate 106 to the circuitry 192 to the circuitry 126 of the first interposer 108. The data signal may optionally be routed through the bridge die 110 prior to being transmitted from the circuitry 192 of the first interposer 108 to the circuitry 126 of the I/O die 122. In the I/O die 122, the data signal is routed through the SERDES circuitry 124 prior to returning to the circuitry 192 of the first interposer 108.

The data signal is then routed from the circuitry 126 of the I/O die 122 to the data routing 148 of the second interposer 112. The data signal is then routed from the data routing 148 of the second interposer 112 to the functional circuitry 202 of the active interposer die 172 within the compute die complex 102. The data signals are routed from the functional circuitry 202 of the active interposer die 172 to the functional circuitry 190 of the compute die 170.

From the functional circuitry 190 of the compute die 170, the data signal is then routed back through the functional circuitry 202 of the active interposer 172 to the memory controller circuitry 162 residing in one or both of the top memory die 142 and/or the bottom memory die 144 via memory routing 248 formed in the second interposer 112.

Data signals read from memory circuitries 164 of the memory dies 142, 144, 146 and/or product by the functional circuitries 190 of the compute dies 170 is routed out of the chip package in the reverse manner.

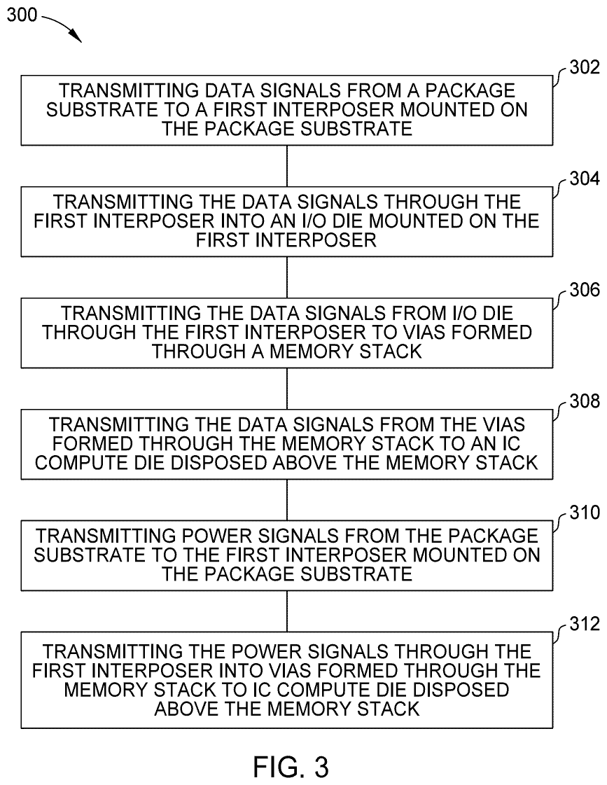

FIG. 3 is flow diagram of one example of a method 300 for operating an electronic device, such as the chip package 100 described above, among others. The method 300 can be followed utilizing the schematic signal routing diagram of FIG. 2A.

The method 300 begins at operation 302 by transmitting data signals from a package substrate to a first interposer mounted on the package substrate. The transmitted data signals may optionally be routed through a bridge die disposed in the first interposer.

At operation 304, data signals are transmitted through the first interposer into an I/O die mounted on the first interposer. In the I/O die, the data signals may be routed through SERDES or other functional circuitry present with the I/O die.

At operation 306, data signals are transmitted from I/O die through the first interposer to vias formed through a memory die stack. At operation 308, the data signals are transmitted from the data vias formed through the memory die stack to an IC compute die disposed above the memory die stack. The data vias formed through the memory die stack shorten the distance required to route signals between the memory die stack and the IC compute die.

At operation 310, power signals are from the package substrate to the first interposer mounted on the package substrate. In the first interposer, the power signals may be coupled to one or more decoupling capacitors. In one example, the decoupling capacitors reside in a bridge die embedded in the first interposer.

At operation 312, the power signals are through the first interposer into power vias formed through the memory stack to IC compute die disposed above the memory stack. The power vias formed through the memory die stack shorten the distance required to route power from the package substrate to the IC compute dies, thus improving the efficiency of power delivery.

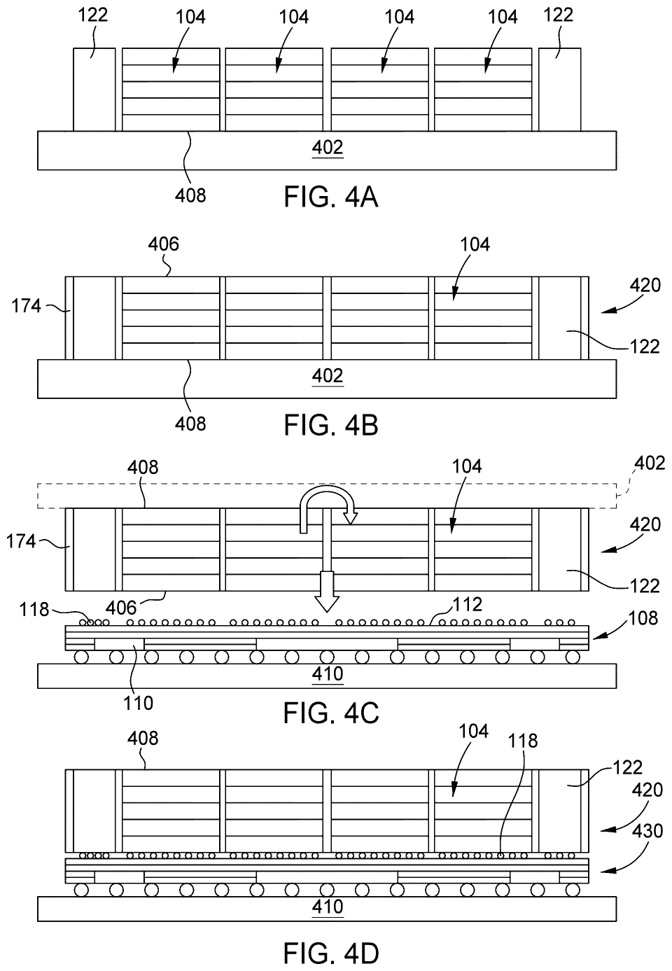

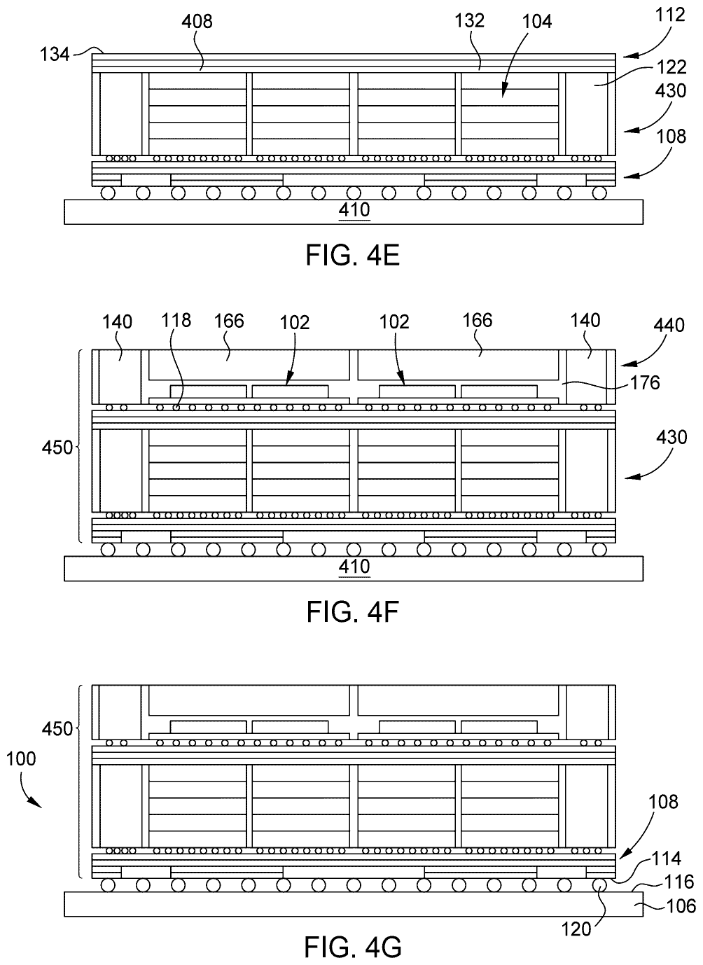

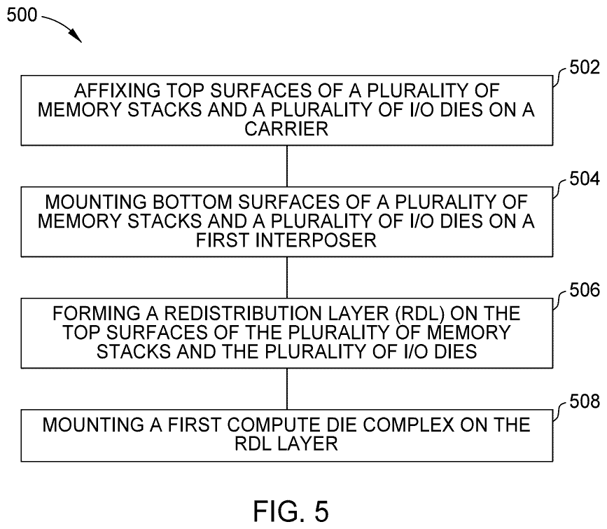

FIG. 4A through FIG. 4G depict a chip package, such as the chip package 100, in various stages of assembly. FIG. 5 is a flow diagram of a method 500 for fabricating one example of a chip package. The stages of fabrication of the method 500 are illustrated by FIGS. 4A-4G.

The method 500 for fabricating a chip package begins at operation 502 by affixing top sides of a plurality of memory die stacks 104 and a plurality of I/O dies 122 on a carrier 402, as illustrated in FIG. 4A. The top sides of the memory die stacks and the I/O dies may be affixed to the carrier by die attach tape or other suitable temporary adhesive that permits latter removal of the carrier.

Once attached to the carrier 402, the memory die stacks and the I/O dies may be encapsulated by a mold compound 174, as illustrated in FIG. 4B, to form a memory-I/O assembly 420. The mold compound may be ground down or otherwise removed to make the mold compound coplanar with the exposed surfaces of the memory die stacks and the I/O dies on the bottom side of the memory die stacks and the I/O dies (i.e., the first side 406 of the memory-I/O assembly 420) that faces away from the carrier.

At operation 504, bottom sides of the plurality of memory die stacks and the plurality of I/O dies are mounted on a first interposer 108, as illustrated in FIGS. 4C-4D. The bottom sides of the memory die stacks and the I/O dies may be electrically and mechanically mounted to the first interposer using solder interconnects. Stated differently, the first side 406 of the memory-I/O assembly 420 is mounted on the first interposer. The carrier 402 is removed from the second side 408 of the memory-I/O assembly 420 at a convenient time.

The first interposer 108 is preformed prior to attaching to the first side 406 of the memory-I/O assembly 420. In one example, the first interposer 108 is fabricated on a second temporary carrier 410 by patterning one or more metal layers that are separated by one or more dielectric layers.

At operation 506, redistribution layer (RDL) layer (e.g., the second interposer 112 shown in FIG. 1A) is formed on the top sides of the plurality of memory die stacks and the plurality of I/O dies, as illustrated in FIG. 4E. Once the RDL layer is formed on the second side 408 of the memory-I/O assembly 420, the resulting structure can be referred to as an RDL-memory-I/O assembly 430.

At operation 508, a first compute die complex is mounted on the RDL layer. The first compute die complex may be electrically and mechanically mounted to the first interposer using solder interconnects, as illustrated in FIG. 4F. In one example, the first compute die complex 102 is part of a compute die complex assembly 440 that includes one or more compute die complexes 102, one or more optional dummy dies 140, and one or more optional carrier dies 166 held together by mold compound 176. Thus, the compute die complex assembly 440 electrically and mechanically mounted to the first interposer using solder interconnects. As the compute die complex assembly 440 is fabricated separately from the memory-I/O assembly 420, the configuration of the final chip package 100 is scalable and flexible, allowing for reduced design and fabrication cycle times, along with reduced costs. Moreover, testing of the compounds of the compute die complex assembly 440 and the memory-I/O assembly 420 prior to assembly into the chip package 100 results in increased production yields.

After operation 508 is complete, the carrier 410 is removed and the package substrate 106 is coupled to the bottom side 114 of the first interposer 108 via solder balls 120, as illustrated in FIG. 4G, to form the chip package 100. The chip package 100 may later be mounted to a PCB 186 (as shown phantom in FIG. 1A) to form an electronic device 160.

Thus, the chip packages disclosed above leverage through memory die stack vias to integrate compute and memory dies in a multi-tier stack. Generally, the stacked compute and memory dies leverages embedded fanout bridge (EFB), chip on wafer on substrate (CoWoS), and redistribution layer (RDL) fabrication techniques to yield chip packages having shorter routings, better performance and greater fabrication yields as compared to conventional arrangements that utilize conventional fabrication processes. Short routing lengths beneficially result in less energy consumed while transferring data between logic die and memory. Moreover, the use of solder based interconnects between the compute die and the memory die stack improves fabrication yield since the memory die stacks can be built and tested prior to combining with the compute dies. Furthermore, power vias formed through the memory die stacks provide more efficient power delivery. The multi-tier stack improves wafer utilization, while also improving thermal management within the chip package, improves wafer utilization, and further enables improved design and fabrication cycle times with reduced costs. The separate and modular arrangement of the chip package components also enables increased manufacturing flexibility, with the number and position of the modular components of the chip package enabling multiple compute applications without the need for new die or interposer designs. As a result, the chip package provides increased application flexibility at reduced manufacturing costs.

In addition to the examples described above, the disclosed technology may also be expressed in the following non-limiting examples.

Example 1. A chip package including: a first memory die stack having a first side mounted to a first interposer; a first I/O die having a first side mounted to the first interposer; and a first compute die complex mounted on a second side of the first memory die stack, the first compute die complex including at least a first compute die having functional circuitry coupled to circuitry of the first I/O die through vias extending through the first memory die stack.

Example 2. The chip package of Example 1, wherein the circuitry of the first I/O die is coupled to the vias extending through the first memory die stack by routing formed in the first interposer.

Example 3. The chip package of Example 2, wherein the first interposer further includes: a bridge die having circuitry coupling the circuitry of the first I/O die and the vias extending through the first memory die stack.

Example 4. The chip package of Example 2, wherein the bridge die further includes: one or more decoupling capacitors.

Example 5. The chip package of Example 1 further including: a second interposer disposed between the first compute die complex and the second side of the first memory die stack, the functional circuitry of the first compute die coupled to the vias extending through the first memory die stack through routing formed in the second interposer.

Example 6. The chip package of Example 5, wherein the second interposer is a redistribution layer, and wherein the first interposer is an organic interposer.

Example 7. The chip package of Example 5 further including: a dummy die mounted to the second interposer above the first I/O die; and one or more metal paths formed in the second interposer and extending between the dummy die and the first I/O die.

Example 8. The chip package of Example 7 further including: a silicon carrier mounted to the first compute die complex.

Example 9. The chip package of Example 5 further including: a dummy die mounted to the second interposer above the first I/O die; and one or more metal paths formed in the second interposer and extending between the dummy die and the first I/O die; and a silicon carrier mounted to the first compute die complex, wherein top sides of the dummy die and the first compute die complex are coplanar.

Example 10. The chip package of Example 9 further including: a substrate having the first interposer coupled thereto via solder balls.

Example 11. The chip package of Example 1 further including: a second memory die stack coupled between the first compute die complex and the first interposer, the second memory die stack having via electrically coupling the first compute die complex to the circuitry of the first I/O die.

Example 12. The chip package of Example 11, wherein the first compute die complex further includes: a second compute die; and an active interposer upon which the first and second compute dies are mounted.

Example 13. The chip package of Example 12, wherein the active interposer of the first compute die complex is coupled to a second interposer disposed between the first compute die complex and the first and second memory die stacks by solder interconnects.

Example 14. The chip package of Example 12, wherein the first compute die includes accelerated compute core circuitry.

Example 15. The chip package of Example 12, wherein the first compute die includes central processing unit (CPU) core circuitry.

Example 16. The chip package of Example 1, wherein the first memory die stack further includes: a base die including memory controller circuitry; and a plurality of memory dies stacked with the base die, the plurality of memory dies disposed between the base die and the first compute die complex.

Example 17. The chip package of Example 1, wherein the first memory die stack further includes: a plurality of memory dies; and a base die including memory controller circuitry, the base die stacked with the plurality of memory dies, the base die disposed between the plurality of memory dies and the first compute die complex.

Example 18. The chip package of Example 1 further including: a second memory die stack mounted to the first interposer; a second I/O die mounted to the first interposer; and a second compute die complex mounted on the second memory die stack, the second compute die complex including at least a second compute die having functional circuitry coupled to circuitry of the second I/O die through vias extending through the second memory die stack.

Example 19. The chip package of Example 18, wherein the first and second memory die stacks are disposed between the first and second I/O dies.

Example 20. The chip package of Example 19, wherein the first interposer further includes: a plurality of power contact pads predominantly located below the first and second memory die stacks; and a plurality of data signal contact pads predominantly outward of the first and second memory die stacks.

Example 21. A chip package including: a first interposer; a first memory die stack mounted to the first interposer; a second memory die stack mounted to the first interposer laterally adjacent the first memory die stack; a first I/O die mounted to the first interposer; a second I/O die mounted to the first interposer, the first and second die stacks disposed between the first and second I/O dies; a second interposer disposed on the first and second die stacks and the first and second I/O dies; a first compute die complex mounted on the second interposer above the first and second memory die stacks, the first compute die complex including at least a first compute die having functional circuitry coupled to circuitry of the first I/O die through vias extending through the first memory die stack.

Example 22. The chip package of Example 21, wherein the circuitry of the first I/O die is coupled to the vias extending through the first memory die stack by routing formed in the first interposer.

Example 23. The chip package of Example 22, wherein the first interposer further includes: a bridge die having circuitry coupling the circuitry of the first I/O die and the vias extending through the first memory die stack.

Example 24. The chip package of Example 22, wherein the bridge die further includes: one or more decoupling capacitors.

Example 25. The chip package of Example 21, wherein the second interposer is a redistribution layer, and wherein the first interposer is an organic interposer.

Example 26. The chip package of Example 21 further including: a first dummy die mounted to the second interposer above the first I/O die; and a second dummy die mounted to the second interposer above the second I/O die; and metal paths formed in the second interposer, the metal paths extending between the first dummy die and the first I/O die and extending between the second dummy die and the second I/O die.

Example 27. The chip package of Example 21 further including: a silicon carrier mounted to the first compute die complex.

Example 28. The chip package of Example 27 further including: a first dummy die mounted to the second interposer above the first I/O die; and a second dummy die mounted to the second interposer above the second I/O die, wherein top sides of the dummy die and the first compute die complex are coplanar.

Example 29. The chip package of Example 21, wherein the first compute die complex further includes: a second compute die; and an active interposer upon which the first and second compute dies are mounted.

Example 30. The chip package of Example 29, wherein the active interposer of the first compute die complex is coupled to a second interposer disposed between the first compute die complex and the first and second memory die stacks by solder interconnects.

Example 31. The chip package of Example 21, wherein the first compute die includes accelerated compute core circuitry.

Example 32. The chip package of Example 21, wherein the first compute die includes central processing unit (CPU) core circuitry.

Example 33. The chip package of Example 21, wherein the first memory die stack further includes: a base die including memory controller circuitry; and a plurality of memory dies stacked with the base die, the plurality of memory dies disposed between the base die and the first compute die complex.

Example 34. The chip package of Example 21, wherein the first memory die stack further includes: a plurality of memory dies; and a base die including memory controller circuitry, the base die stacked with the plurality of memory dies, the base die disposed between the plurality of memory dies and the first compute die complex.

Example 35. The chip package of Example 21 further including: a fourth memory die stack mounted to the first interposer between the second memory die stack and the second I/O die; a fifth memory die stack mounted to the first interposer between the second memory die stack and the second I/O die; a second compute die complex mounted on the fourth and fifth memory die stacks, the second compute die complex including at least a second compute die having functional circuitry coupled to circuitry of the second I/O die through vias extending through the at least one of the fourth and fifth memory die stacks.

Example 36. The chip package of Example 21, wherein the first interposer further includes: a plurality of power contact pads predominantly located below the first and second memory die stacks relative to a region of the first interposer upon which the first and second I/O dies are mounted; and a plurality of data signal contact pads predominantly outward of the first and second memory die stacks relative to a region of the first interposer upon which the first and second memory die stacks are mounted.

Example 37. The chip package of Example 21, wherein the first I/O die further includes: SERDES circuitry.

Example 38. A method for operating a chip package, the method including: transmitting data signals from a package substrate to a first interposer mounted on the package substrate; transmitting the data signals through the first interposer into an I/O die mounted on the first interposer; transmitting the data signals from I/O die mounted through the first interposer to vias formed through a memory die stack; and transmitting the data signals from the vias formed through the memory die stack to an IC compute die disposed above the memory die stack.

Example 39. The method of Example 38 further including: transmitting power signals from the package substrate to the IC compute die through vias formed in the memory die stack, the power signals transmitted to the IC compute die bypassing the I/O die.

Example 40. The method of Example 38, wherein the transmitted power signals are coupled to decoupled capacitors located in a bridge die disposed within the first interposer.

Example 41. The method of Example 38, wherein the transmitted power signals and the transmitted data signals pass through a second interposer disposed between the memory die stack and the IC compute die.

Example 42. A method for fabricating a chip package, the method including operations of affixing top sides of a plurality of memory die stacks and a plurality of I/O dies on a carrier; mounting bottom sides of a plurality of memory die stacks and a plurality of I/O dies on a first interposer; forming a redistribution layer (RDL) layer on the top sides of the plurality of memory die stacks and the plurality of I/O dies; and mounting a first compute die complex on the RDL layer.

Example 43. The method of Example 42 further including operations of mounting a second compute die complex on the RDL layer next to the first compute die complex.

Example 44. The method of Example 43 further including operations of mounting dummy dies to the RDL layer outward for the first and second compute die complexes.

Example 45. The method of Example 44 further including operations of mounting carrier silicon blocks on the first and second compute die complexes.

Example 46. The method of Example 42, wherein the interposer includes a bridge dies electrically connecting one of the I/O dies to the first compute die complex.

Example 47. A chip package including: a die stack having a first side mounted to a first interposer; a first I/O die having a first side mounted to the first interposer; and a first compute die complex mounted on a second side of the die stack, the first compute die complex including at least a first compute die having functional circuitry coupled to circuitry of the first I/O die through vias extending through the die stack.

Example 48. The chip package of Examiner 47, wherein the die stack comprise a homogeneous stack of ASIC dies, a homogeneous stack of compute dies, a homogeneous stack of other types of IC dies, a heterogeneous stack of ASIC dies, a heterogeneous stack of compute dies, a heterogeneous stack of other types of IC dies, among others.

Example 49. The chip package of Examiner 47, wherein the die stack comprise at least one IC die selected from the group consisting of an ASIC die, a compute die, and a memory die.

Example 50. A chip package including: a die stack having a first side mounted to a first interposer; a first I/O die having a first side mounted to the first interposer, the compute die disposed laterally adjacent the die stack; and a first compute die complex mounted on a second side of the die stack, the first compute die complex including at least a first compute die.

Example 51. The chip package of Example 50, wherein the first compute die has functional circuitry coupled to circuitry of the first I/O die through vias extending through the die stack.

Example 52. The chip package of Example 50, wherein the first compute die has functional circuitry coupled to circuitry of the first I/O die while by-passing the die stack.

Example 53. The chip package of Example 50, wherein power routings and/or ground routings connect to the first compute die through the first I/O die while by-passing the die stack.

While the foregoing is directed to embodiments of the present invention, other and further embodiments of the invention may be devised without departing from the basic scope thereof, and the scope thereof is determined by the claims that follow.

What is claimed is:

1. A chip package comprising:
a first die stack having a first side mounted to a first interposer;
a first I/O die having a first side mounted to the first interposer; and
a first compute die complex mounted on a second side of the first die stack, the first compute die complex including at least a first compute die having functional circuitry coupled to circuitry of the first I/O die through vias extending through the first die stack.

2. The chip package of claim 1, wherein the circuitry of the first I/O die is coupled to the vias extending through the first die stack by routing formed in the first interposer.

3. The chip package of claim 2, wherein the first interposer further comprises:
a bridge die having circuitry coupling the circuitry of the first I/O die and the vias extending through the first die stack.

4. The chip package of claim 3, wherein the bridge die further comprises:
one or more decoupling capacitors.

5. The chip package of claim 1 further comprising:
a second interposer disposed between the first compute die complex and the second side of the first die stack, the functional circuitry of the first compute die coupled to the vias extending through the first die stack through routing formed in the second interposer.

6. The chip package of claim 5, wherein the second interposer is a redistribution layer, and wherein the first interposer is an organic interposer.

7. The chip package of claim 1 further comprising:
a second die stack coupled between the first compute die complex and the first interposer, the memory die stack having via electrically coupling the first compute die complex to the circuitry of the first I/O die, wherein the first and second die stacks are memory die stacks.

8. The chip package of claim 7, wherein the first compute die complex further comprises:
a second compute die; and
an active interposer upon which the first and second compute dies are mounted.

9. The chip package of claim 8, wherein the first compute die includes accelerated compute core circuitry and/or central processing unit (CPU) core circuitry.

10. The chip package of claim 1, wherein the first die stack is a memory die stack, the memory die stack further comprising:
a base die including memory controller circuitry; and
a plurality of memory dies stacked with the base die, the plurality of memory dies disposed between the base die and the first compute die complex.

11. The chip package of claim 1, wherein the first die stack is a memory die stack, the memory die stack further comprising:
a plurality of memory dies; and
a base die including memory controller circuitry, the base die stacked with the plurality of memory dies, the base die disposed between the plurality of memory dies and the first compute die complex.

12. A chip package comprising:
a first interposer;
a first memory die stack mounted to the first interposer;
a second memory die stack mounted to the first interposer laterally adjacent the first memory die stack;
a first I/O die mounted to the first interposer;
a second I/O die mounted to the first interposer, the first and second die stacks disposed between the first and second I/O dies;
a second interposer disposed on the first and second die stacks and the first and second I/O dies; and
a first compute die complex mounted on the second interposer above the first and second memory die stacks, the first compute die complex including at least a first compute die having functional circuitry coupled to circuitry of the first I/O die through vias extending through the first memory die stack.

13. The chip package of claim 12, wherein the circuitry of the first I/O die is coupled to the vias extending through the first memory die stack by routing formed in the first interposer.

14. The chip package of claim 13, wherein the first interposer further comprises:
a bridge die having circuitry coupling the circuitry of the first I/O die and the vias extending through the first memory die stack.

15. The chip package of claim 14, wherein the bridge die further comprises:
one or more decoupling capacitors.

16. The chip package of claim 12, wherein the second interposer is a redistribution layer, and wherein the first interposer is an organic interposer.

17. The chip package of claim 12 further comprising:
a silicon carrier mounted to the first compute die complex;
a first dummy die mounted to the second interposer above the first I/O die; and
a second dummy die mounted to the second interposer above the second I/O die, wherein top sides of the dummy die and the first compute die complex are coplanar.

18. The chip package of claim 12, wherein the first compute die complex further comprises:
a second compute die;
an active interposer upon which the first and second compute dies are mounted, wherein the active interposer of the first compute die complex is coupled to a second interposer disposed between the first compute die complex and the first and second memory die stacks by solder interconnects.

19. A method for operating a chip package, the method comprising:
transmitting data signals from a package substrate to a first interposer mounted on the package substrate;
transmitting the data signals through the first interposer into an I/O die mounted on the first interposer;
transmitting the data signals from I/O die mounted through the first interposer to vias formed through a memory die stack; and
transmitting the data signals from the vias formed through the memory die stack to an IC compute die disposed above the memory die stack.

20. The method of claim 19 further comprising:
transmitting power signals from the package substrate to the IC compute die through vias formed in the memory die stack, the power signals transmitted to the IC compute die bypassing the I/O die, wherein the transmitted power signals are coupled to decoupled capacitors located in a bridge die disposed within the first interposer, and wherein the transmitted power signals and the transmitted data signals pass through a second interposer disposed between the memory die stack and the IC compute die.
